(19) United States
(12) Patent Application Publication
(10) Pub. No.: US 2010/0200734 A1
(43) Pub. Date: Aug. 12, 2010

(54) POWER SUPPLY CIRCUIT AND OPTICAL RECEIVING CIRCUIT

(75) Inventor: Toyoaki Uo, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/699,209

(22) Filed: Feb. 3, 2010

(30) Foreign Application Priority Data
Feb. 10, 2009 (JP) 2009-028907

(51) Int. Cl. H01L 31/09; G05F 3/02

(52) U.S. Cl. 250/214 R; 327/535

(57) ABSTRACT

A power supply circuit includes: a start-up circuit provided on a semiconductor substrate and configured to convert an optical signal to an electrical signal; and a bias circuit provided on the semiconductor substrate and being in a non-start-up state at power-on, the start-up circuit including: a p-type semiconductor region; and an n-type semiconductor region provided in contact with the p-type semiconductor region, the p-type semiconductor region being electrically connected to the bias circuit, the n-type semiconductor region being electrically connected to a power supply of the bias circuit, and the bias circuit entering a start-up state by a current flowing in the start-up circuit.

### CROSS-REFERENCE TO RELATED APPLICATIONS

This application is based upon and claims the benefit of priority from the prior Japanese Patent Application No. 2009-28907, filed on Feb. 10, 2009; the entire contents of which are incorporated herein by reference.

### BACKGROUND OF THE INVENTION

1. Field of the Invention

This invention relates to a power supply circuit and an optical receiving circuit characterized by a start-up circuit.

2. Background Art

Electronic circuits include bias circuits such as a current source and voltage source. Some of these bias circuits do not automatically enter the start-up state at power-on and require a start-up circuit to start operation. For instance, a self-biasing current source circuit is known to require a start-up circuit composed of a diode, resistor and the like (see, e.g., P. R. Gray, P. J. Hurst, S. H. Lewis, and R. G. Meyer, Analysis and Design of Analog Integrated Circuits, 4th ed., Baifukan, Tokyo, Jul. 10, 2003, pp. 358-369, Japanese translation from the original 4th ed.).

With the reduction of power consumption in electronic devices, electronic circuits are also developed for lower power consumption. In an optical receiving circuit, the detection output from an optical signal detection circuit is used to control the operation of a power supply circuit, thereby reducing power consumption. For instance, when no optical signal is inputted to the optical receiving element, the power supply circuit outputs a low operating voltage, and hence the amplifier circuit is in standby state and achieves low power consumption. When an optical signal is inputted to the optical receiving element, the power supply circuit outputs an operating voltage with a value enough to operate the amplifier circuit.

With regard to an optical receiving circuit including an optical receiving element for converting an optical signal to an electrical signal, there is also a proposal for controlling the behavior of the optical receiving circuit by the variation of the electrical signal of the optical receiving element in response to the optical signal (see, e.g., JP-A 7-098249 (1995)(Kokai)).

However, the aforementioned start-up circuit has the problem of variation in the start-up current flowing in the start-up circuit when an intense optical signal is entered.

### SUMMARY OF THE INVENTION

According to an aspect of the invention, there is provided a power supply circuit including: a start-up circuit provided on a semiconductor substrate and configured to convert an optical signal to an electrical signal; and a bias circuit provided on the semiconductor substrate and being in a non-start-up state at power-on, the start-up circuit including: a p-type semiconductor region; and an n-type semiconductor region provided in contact with the p-type semiconductor region, the p-type semiconductor region being electrically connected to the bias circuit, the n-type semiconductor region being electrically connected to a power supply of the bias circuit, and the bias circuit entering a start-up state by a current flowing in the start-up circuit.

According to another aspect of the invention, there is provided a power supply circuit including: a start-up circuit provided on a semiconductor substrate and configured to convert an optical signal to an electrical signal; and a bias circuit provided on the semiconductor substrate and being in a non-start-up state at power-on, the start-up circuit including: an n-type semiconductor region; and a p-type semiconductor region provided in contact with the n-type semiconductor region, the n-type semiconductor region being electrically connected to the bias circuit, the p-type semiconductor region being electrically connected to ground of the bias circuit, and the bias circuit entering a start-up state by a current flowing in the start-up circuit.

According to still another aspect of the invention, there is provided an optical receiving circuit including: a power supply circuit; a photocurrent converting element configured to convert optical energy to an electrical signal; a current-voltage converting circuit configured to convert an output of the photocurrent converting element to a voltage; and an output circuit configured to output an output of the current-voltage converting circuit, the power supply circuit including: a start-up circuit provided on a semiconductor substrate and configured to convert an optical signal to an electrical signal; and a bias circuit provided on the semiconductor substrate and being in a non-start-up state at power-on, the start-up circuit including: a first conductivity type semiconductor region; and a second conductivity type semiconductor region provided in contact with the first conductivity type semiconductor region, the first conductivity type semiconductor region being electrically connected to the bias circuit, the second conductivity type semiconductor region being electrically connected to a power supply of the bias circuit or ground, and the bias circuit entering a start-up state by a current flowing in the start-up circuit.

### BRIEF DESCRIPTION OF THE DRAWINGS

FIG. 1 is a block diagram illustrating the configuration of a power supply circuit according to a first embodiment of the invention;

FIG. 2 is a circuit diagram illustrating the power supply circuit according a practical example of the invention;

FIG. 3 is a schematic cross-sectional view of the transistor of the start-up circuit shown in FIG. 2;

FIG. 4 shows a diagram explaining the operation of the current source circuit shown in FIG. 2;

FIG. 5 is a circuit diagram illustrating another practical example of the invention;

FIG. 6 is a schematic cross-sectional view of the transistor of the start-up circuit shown in FIG. 5;

FIG. 7 is a circuit diagram illustrating another practical example of the invention;

FIG. 8 is a schematic cross-sectional view of the diffusion resistor of the start-up circuit shown in FIG. 7;

FIG. 9 is a block diagram illustrating the configuration of a power supply circuit according to another embodiment of the invention;

FIG. 10 is a circuit diagram illustrating another practical example of the invention;

FIG. 11 is a circuit diagram illustrating another practical example of the invention;

FIG. 12 is a circuit diagram illustrating another practical example of the invention;

FIG. 13 is a schematic cross-sectional view of the capacitor of the start-up circuit shown in FIG. 12;

FIG. 14 is a block diagram illustrating the configuration of a power supply circuit according to another embodiment of the invention;

FIG. 15 is a circuit diagram illustrating another practical example of the invention;

FIG. 16 is a circuit diagram illustrating another practical example of the invention;

FIG. 17 is a circuit diagram illustrating another practical example of the invention;

FIG. 18 is a block diagram illustrating the configuration of a power supply circuit according to another embodiment of the invention;

FIG. 19 is a circuit diagram illustrating another practical example of the invention;

FIG. 20 is a circuit diagram illustrating another practical example of the invention;

FIG. 21 is a circuit diagram illustrating another practical example of the invention;

FIG. 22 is a block diagram illustrating the configuration of a power supply circuit according to another embodiment of the invention; and

FIG. 23 is a block diagram illustrating the configuration of an optical receiving circuit according to another embodiment of the invention.

### DETAILED DESCRIPTION OF THE INVENTION

Embodiments of the invention will now be described in detail with reference to the drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In the specification and the drawings, the same elements as those described previously with reference to earlier figures are labeled with like reference numerals, and the detailed description thereof is omitted as appropriate.

### First Embodiment

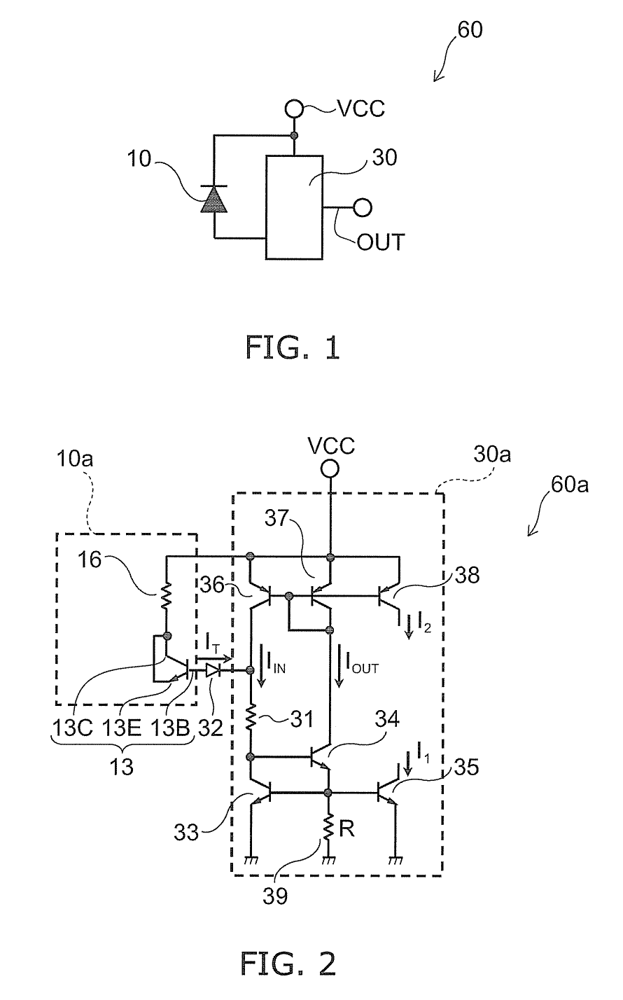

FIG. 1 is a block diagram illustrating the configuration of a power supply circuit according to a first embodiment of the invention.

As shown in FIG. 1, the power supply circuit 60 has a one-chip structure in which a bias circuit 30 and a start-up circuit 10 are formed in the same semiconductor substrate.

The bias circuit 30 is an electronic circuit connected to the output of the start-up circuit 10 and supplying a bias OUT to the outside. However, the bias circuit 30 is an electronic circuit requiring a start-up circuit, and does not operate even if power is applied. When an optical signal is entered after power-on, or at power-on while an optical signal is entered, the bias circuit normally starts operation by a photocurrent from the start-up circuit 10.

Thus, the power supply circuit 60 is a power supply, which supplies the bias OUT to the outside not immediately when the power is on, but when an optical signal is further entered.

The start-up circuit 10 serves to convert an optical signal to an electrical signal. When an optical signal is inputted, the start-up circuit 10 supplies a photocurrent to the bias circuit 30 and places it in start-up state. In this practical example, the start-up circuit 10 is illustratively composed of a photodiode, and its p-type semiconductor region (first conductivity type semiconductor region) is electrically connected to the bias circuit 30. However, the invention is not limited thereto. The start-up circuit 10 can be composed of any element converting an optical signal to an electrical signal, such as a parasitic diode of a bipolar transistor, resistor or the like, and its p-type semiconductor region (first conductivity type semiconductor region) can be electrically connected to the bias circuit 30.

FIG. 2 is a circuit diagram illustrating the power supply circuit according the practical example of the invention.

As shown in FIG. 2, the power supply circuit 60a has a one-chip structure in which a bias circuit 30a and a start-up circuit 10a are formed in the same semiconductor substrate.

In the power supply circuit 60a, the bias circuit 30a requiring a start-up circuit is illustratively a self-biasing current source circuit referenced to the base-emitter voltage Vbe. The start-up circuit 10a includes an NPN transistor 13 and a limiting resistor 16.

The NPN transistor 13 includes a collector 13C, an emitter 13E, and a base 13B. The collector 13C and the emitter 13E are connected to one end of the limiting resistor 16. The other end of the limiting resistor 16 is connected to high potential, such as a power supply VCC. The base 13B is connected to the bias circuit 30a through a diode 32.

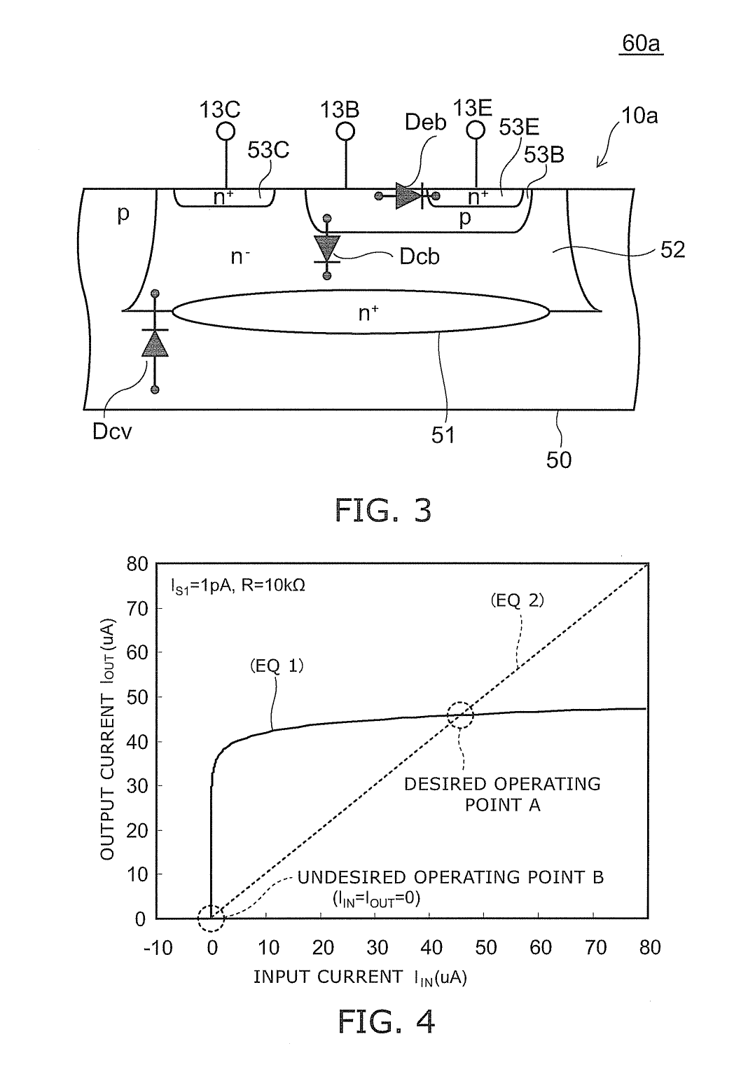

FIG. 3 is a schematic cross-sectional view of the transistor of the start-up circuit shown in FIG. 2.

As shown in FIG. 3, the NPN transistor 13 of the start-up circuit 10a is a bipolar transistor provided on a p-type semiconductor substrate 50. An n⁻-well region 52 (n-type semiconductor region, second conductivity type semiconductor region) is provided on an n⁺-buried layer 51 provided in the p-type semiconductor substrate 50. A p-well region 53B (p-type semiconductor region, first conductivity type semiconductor region) is provided in the n⁻-well region 52 (n-type semiconductor region, second conductivity type semiconductor region) and serves as a base 13B.

Furthermore, an n⁺-contact layer 53E (n-type semiconductor region, second conductivity type semiconductor region) is provided in the p-well region 53B (p-type semiconductor region, first conductivity type semiconductor region) and serves as an emitter 13E. Moreover, an n⁺-contact layer 53C (n-type semiconductor region, second conductivity type semiconductor region) is provided in the n⁻-well region 52 and serves as a collector 13C.

As described above, the base 13B is connected to the bias circuit 30a through the diode 32. Hence, the p-well region 53B (p-type semiconductor region, first conductivity type semiconductor region) is electrically connected to the bias circuit 30a.

As described later, when there is no optical irradiation and the start-up circuit 10a does not act on the bias circuit 30a, no current flows in the bias circuit 30a. Hence, the base-emitter voltage Vbe of the NPN transistors 33 and 34 is nearly zero, and the base 13B of the NPN transistor 13 is placed at low potential (ground potential).

Because the collector 13C and the emitter 13E are placed at high potential and the base 13B is placed at low potential, the collector-substrate junction (between the n⁻-well region 52 and the p-type semiconductor substrate 50), the collector-base junction (between the n⁻-well region 52 and the p-well region 53B), and the emitter-base junction (between the n⁺-contact layer 53E and the p-well region 53B) are reverse biased and create reverse biased parasitic diodes Dcv, Dcb, and Deb, respectively.

In the case where there is no optical signal, the parasitic diodes Dcv, Dcb, and Deb are reverse biased, and current barely flows therein. Hence, because the base current and the collector current barely flow in the NPN transistor 13, it passes no start-up current to the bias circuit 30a.

Next, the operation in the presence of an optical signal is described. Because the parasitic diodes Dcv, Dcb, and Deb are reverse biased, an optical signal entered thereto is photoelectrically converted at each junction interface, and a current flows from the cathode toward the anode of each of the parasitic diodes Dcv, Dcb, and Deb. Because the collector 13C and the emitter 13E are connected to the high potential side, the current flowing in each of the parasitic diodes Dcv, Dcb, and Deb is supplied from the collector and emitter terminal 13C, 13E.

In the parasitic diode Dcv, the current flows from the collector 13C toward the p-type semiconductor substrate 50. In the parasitic diode Dcb, the current flows from the collector 13C to the base 13B. In the parasitic diode Deb, the current flows from the emitter 13E toward the base 13B. Hence, the current flowing in the parasitic diodes Dcb and Deb flows out from the base 13B of the NPN transistor 13.

When an optical signal is entered after power-on, or at power-on while an optical signal is entered, a current flows out from the base 13B of the NPN transistor 13, and a start-up current I_{T} is passed to the bias circuit 30a. Thus, the NPN transistor 13 and the limiting resistor 16 operate as a start-up circuit for the bias circuit 30a as described later. Here, although the limiting resistor 16 is inserted to limit the photocurrent, it may be omitted.

Returning to FIG. 2, the operation of the bias circuit 30a is described. The bias circuit 30a is a self-biasing current source circuit referenced to the base-emitter voltage Vbe, and is known as a bias circuit requiring a start-up circuit.

First, the operation of the bias circuit 30a is described in the case where the resistor 31 is short-circuited and the diode 32 is not provided, that is, in the case where there is no action of the start-up circuit 10a.

The transistors 33 and 34 and the resistor 39 constitute a current source referenced to the base-emitter voltage Vbe. The current I_{IN} flowing in the transistor 33 equals the current I₁ flowing in the transistor 35.

On the other hand, the transistors 36 and 37 constitute a current mirror circuit, which mirrors the output current I_{OUT} of the current source referenced to the base-emitter voltage Vbe to output a current I_{IN}. This current is the input current of the current source referenced to the base-emitter voltage Vbe. Thus, the current source referenced to the base-emitter voltage Vbe and the current mirror circuit composed of the transistors 36 and 37 constitute a positive feedback circuit in which the input current of one circuit is determined by the output current of the other, and is called a self-biased circuit. Here, the current flowing in the transistor 36 equals the current I₂ flowing in the transistor 38.

The relationship between the input current and the output current of the current source circuit referenced to the base-emitter voltage Vbe is given by equation (1), neglecting the base current of the transistor 34:

Iₒᵤₜ=(V_{T}/R)·ln(I_{IN}/I_{S1}) (1)

Where, R is the resistance of the resistor 39, and I_{S1} is the reverse saturation current. Furthermore, V_{T} is given by the following equation:

V_{T}=kT/q

where, k is Boltzmann's constant, T is absolute temperature, and q is the magnitude of charge of an electron. V_{T} is nearly 26 mV at normal temperature 300 K.

On the other hand, the relationship between the input current and the output current of the current mirror circuit can be expressed as equation (2), neglecting the base current of the transistors 36 and 37:

I_{IN}=I_{OUT} (2)

The input current and the output current I_{OUT} of the current source referenced to the base-emitter voltage Vbe, shown in FIG. 2, are values that simultaneously satisfy both equations (1) and (2).

FIG. 4 shows a calculation example of equations (1) and (2) for I_{S1}=1 pA and R=10 kΩ.

As is obvious from FIG. 4, there are two operating points simultaneously satisfying equations (1) and (2): desired operating point A and undesired operating point B G_{IN}=I_{OUT}=0). Because no current flows at the instant of power-on, the circuit starts from operating point B. At operating point B, because the current of the transistor is nearly zero, the gain around the feedback loop of the current source and the current mirror is often less than or equal to unity, and thus point B is often a stable point. Hence, the bias circuit 30a without the start-up circuit 10a is unable to drive itself out of the zero-current state.

Hence, the bias circuit 30a requires a start-up circuit. A conventionally known start-up circuit includes a plurality of series connected diodes. However, it requires a substantial area for the portion constituting the start-up circuit. Furthermore, under intense optical irradiation, the behavior of the start-up circuit is varied, and it causes the problem of requiring a higher start-up current.

In contrast, in the start-up circuit 10a shown in FIG. 2, when an optical signal is entered after power-on, or at power-on while an optical signal is entered, a current flows out from the base 13B of the NPN transistor 13, and a start-up current I_{T} is passed to the bias circuit 30a through the diode 32. Thus, the NPN transistor 13 and the limiting resistor 16 operate as a start-up circuit for the bias circuit 30a.

In the case where the resistor 31 and the diode 32 shown in FIG. 2 exist, after start-up of the bias circuit 30a, the start-up current I_{T} from the start-up circuit 10a ceases to flow in the bias circuit 30a. After start-up of the bias circuit 30a, the current I_{IN} flows therein, and the collector potential of the transistor 36 is raised by the amount of the voltage drop of the resistor 31. Hence, the diode 32 is reverse biased, and the start-up current I_{T} ceases to flow in the bias circuit 30a. Thus, the bias circuit 30a, which has started operation, becomes stable at operating point A.

Thus, the power supply circuit 60a of this practical example is a power supply circuit allowing start-up control by an optical signal. Furthermore, under intense optical irradiation, the start-up current output of the start-up circuit 10a also increases, and hence the bias circuit 30a can be stably started up.

### Second Practical Example

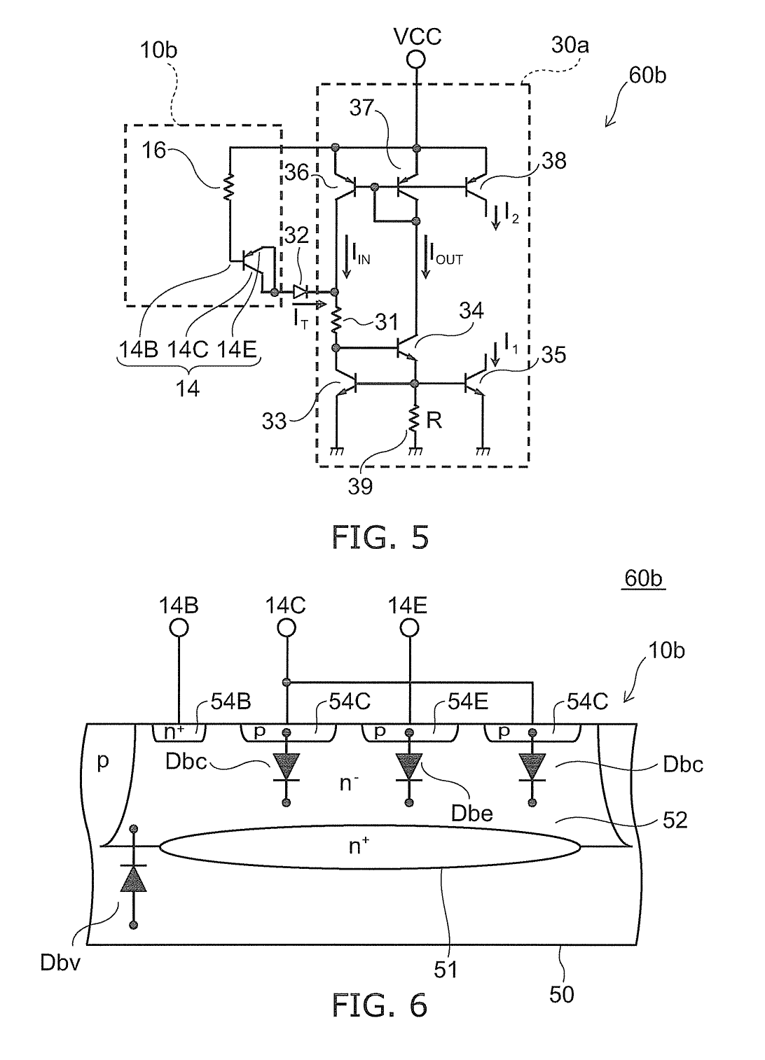

FIG. 5 is a circuit diagram illustrating another practical example of the invention.

As shown in FIG. 5, the power supply circuit 60b has a one-chip structure in which a bias circuit 30a and a start-up circuit 10b are formed in the same semiconductor substrate.

The start-up circuit 10b includes a PNP transistor 14 and a limiting resistor 16.

The PNP transistor 14 includes a collector 14C, an emitter 14E, and a base 14B. The base 14B is connected to one end of the limiting resistor 16. The other end of the limiting resistor 16 is connected to high potential; such as a power supply VCC. In other words, the base 14B is connected to high potential. The collector 14C and the emitter 14E are connected to the bias circuit 30a through a diode 32. The rest is similar to the power supply circuit 60a, and hence the description thereof is omitted.

FIG. 6 is a schematic cross-sectional view of the transistor of the start-up circuit shown in FIG. 5.

As shown in FIG. 6, the PNP transistor 14 of the start-up circuit 10b is a bipolar transistor provided on a p-type semiconductor substrate 50. An n⁻-well region 52 (n-type semiconductor region, second conductivity type semiconductor region) is provided on an n⁺-buried layer 51 provided in the p-type semiconductor substrate 50. An n⁺-contact layer 54B (n-type semiconductor region, second conductivity type semiconductor region) is provided in the n⁻-well region 52 (n-type semiconductor region, second conductivity type semiconductor region) and serves as a base 14B.

Furthermore, a p-type semiconductor region 54E (first conductivity type semiconductor region) is provided in the n⁻-well region 52 (n-type semiconductor region, second conductivity type semiconductor region) and serves as an emitter 14E. Moreover, a p-type semiconductor region 54C (first conductivity type semiconductor region) is provided around the emitter 14E in the n⁻-well region 52 (n-type semiconductor region, second conductivity type semiconductor region) and serves as a collector 14C. The collector 14C and the emitter 14E are connected to the bias circuit 30a through a diode 32. Hence, the p-type semiconductor regions 54C and 54E (first conductivity type semiconductor region) are electrically connected to the bias circuit 30a.

Although the collector 14C is depicted on both sides of the emitter 14E in the schematic cross-sectional view of FIG. 6, the collector 14C surrounds the emitter 14E as viewed in the direction perpendicular to the major surface of the p-type semiconductor substrate 50. The PNP transistor 14 is a lateral transistor.

Because the base 14B is placed at high potential and the collector 14C and the emitter 14E are placed at low potential, the base-substrate junction (between the n⁻-well region 52 and the p-type semiconductor substrate 50), the base-collector junction (between the n⁻-well region 52 and the p-type semiconductor region 54C), and the base-emitter junction (between the n⁻-well region 52 and the p-type semiconductor region 54E) are reverse biased and create reverse biased parasitic diodes Dbv, Dbc, and Dbe, respectively.

In the case where there is no optical signal, the parasitic diodes Dbv, Dbc, and Dbe are reverse biased, and current barely flows therein. Hence, because the base current and the collector current barely flow in the PNP transistor 14, it passes no start-up current to the bias circuit 30a.

Next, the operation in the presence of an optical signal is described. Because the parasitic diodes Dbv, Dbc, and Dbe are reverse biased, an optical signal entered thereto is photoelectrically converted at each junction interface, and a current flows from the cathode toward the anode of each parasitic diode. Because the base 14B is connected to the high potential side, the current flowing in each of the parasitic diodes Dbv, Dbc, and Dbe is supplied from the base 14B. In the parasitic diode Dbv, the current flows from the base 14B toward the p-type semiconductor substrate 50. In the parasitic diode Dbc, the current flows from the base 14B to the collector 14C. In the parasitic diode Dbe, the current flows from the base 14B to the emitter 14E. Hence, the current flowing in the parasitic diodes Dbc and Dbe flows out from the collector 14C and the emitter 14E of the PNP transistor 14.

When an optical signal is entered after power-on, or at power-on while an optical signal is entered, a current flows out from the collector 14C and the emitter 14E of the PNP transistor 14, and a start-up current I_{T} is passed to the bias circuit 30a through the diode 32. Thus, the PNP transistor 14 and the limiting resistor 16 operate as a start-up circuit. Here, the limiting resistor 16 may be omitted as in the power supply circuit 60a.

Thus, the power supply circuit 60b of this practical example is a power supply circuit allowing start-up control by an optical signal. Furthermore, under intense optical irradiation, the start-up current output of the start-up circuit 10b also increases, and hence the bias circuit 30a can be stably started up.

### Third Practical Example

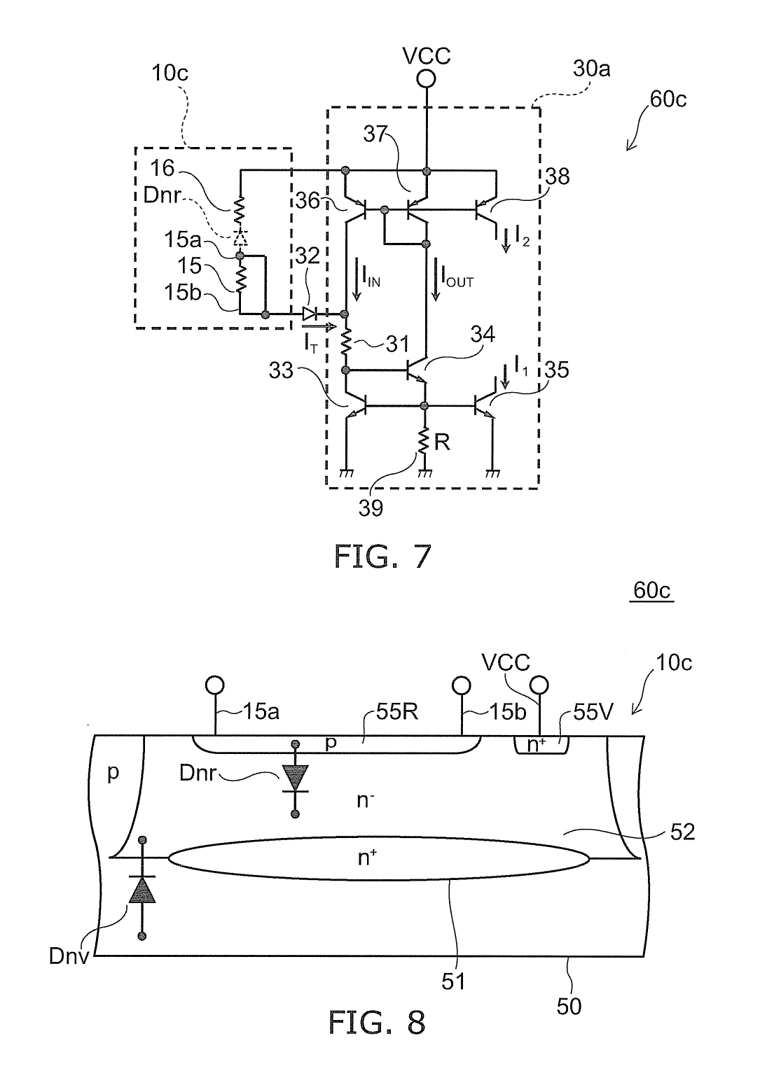

FIG. 7 is a circuit diagram illustrating another practical example of the invention.

As shown in FIG. 7, the power supply circuit 60c has a one-chip structure in which a bias circuit 30a and a start-up circuit 10c are formed in the same semiconductor substrate.

The start-up circuit 10c includes a diffusion resistor 15 and a limiting resistor 16.

Both terminals 15a and 15b of the diffusion resistor 15 are connected to the bias circuit 30a through a diode 32. Furthermore, the diffusion resistor 15 is connected to one end of the limiting resistor 16 through a parasitic diode Dnr. The other end of the limiting resistor 16 is connected to high potential, such as a power supply VCC. In other words, the cathode of the parasitic diode Dnr of the diffusion resistor 15 is connected to high potential. The both terminals 15a and 15b of the diffusion resistor 15 are connected to the bias circuit 30a through the diode 32. The rest is similar to the power supply circuit 60a, and hence the description thereof is omitted.

FIG. 8 is a schematic cross-sectional view of the diffusion resistor of the start-up circuit shown in FIG. 7.

As shown in FIG. 8, the diffusion resistor 15 of the start-up circuit 10c is a diffusion resistor made of a p-type diffusion layer 55R (p-type semiconductor region, first conductivity type semiconductor region) provided on a p-type semiconductor substrate 50. An n⁻-well region 52 (n-type semiconductor region, second conductivity type semiconductor region) is provided on an n⁺-buried layer 51 provided in the p-type semiconductor substrate 50. An n⁺-contact layer 55V (n-type semiconductor region, second conductivity type semiconductor region) is provided in the n⁻-well region 52 (n-type semiconductor region, second conductivity type semiconductor region) and connected to high potential, such as a power supply VCC.

Furthermore, a p-type diffusion layer 55R (p-type semiconductor region, first conductivity type semiconductor region) is provided in the n⁻-well region 52 (n-type semiconductor region, second conductivity type semiconductor region) and serves as a diffusion resistor 15 by extracting terminals 15a and 15b from its both ends.

Because the both terminals 15a and 15b of the diffusion resistor 15 are connected to the bias circuit 30a through the diode 32, the p-type diffusion layer 55R (p-type semiconductor region, first conductivity type semiconductor region) is electrically connected to the bias circuit 30a.

Because the n⁻-well region 52 (n-type semiconductor region, second conductivity type semiconductor region) is placed at high potential and the diffusion resistor 15 (p-type diffusion layer 55R) (p-type semiconductor region, first conductivity type semiconductor region) is placed at low potential, the junction between the n⁻-well region 52 (n-type semiconductor region, second conductivity type semiconductor region) and the p-type semiconductor substrate 50, and the junction between the n⁻-well region 52 (n-type semiconductor region, second conductivity type semiconductor region) and the p-type diffusion layer 55R (p-type semiconductor region, first conductivity type semiconductor region) are reverse biased and create reverse biased parasitic diodes Dnv and Dnr, respectively.

In the case where there is no optical signal, the parasitic diodes Dnv and Dnr are reverse biased, and current barely flows therein. Hence, no start-up current is passed from the diffusion resistor 15 to the bias circuit 30a.

Next, the operation in the presence of an optical signal is described. Because the parasitic diodes Dnv and Dnr are reverse biased, an optical signal applied thereto is photoelectrically converted at each junction interface, and a current flows from the cathode toward the anode of each parasitic diode. Because the n⁻-well region 52 (n-type semiconductor region, second conductivity type semiconductor region) is connected to the high potential side through the n⁺-contact layer 55V (n-type semiconductor region, second conductivity type semiconductor region), the current flowing in each of the parasitic diodes Dnv and Dnr is supplied from the n⁻-well region 52 (n-type semiconductor region, second conductivity type semiconductor region).

In the parasitic diode Dnv, the current flows from the n⁻-well region 52 (n-type semiconductor region, second conductivity type semiconductor region) toward the p-type semiconductor substrate 50. In the parasitic diode Dnr, the current flows from the n⁻-well region 52 (n-type semiconductor region, second conductivity type semiconductor region) to the diffusion resistor 15 (p-type semiconductor region, first conductivity type semiconductor region). Hence, the current flowing in the parasitic diode Dnr flows out from both terminals 15a and 15b of the diffusion resistor 15 (p-type semiconductor region, first conductivity type semiconductor region).

When an optical signal is entered after power-on, or at power-on while an optical signal is entered, a current flows out from both terminals 15a and 15b of the diffusion resistor 15 (p-type semiconductor region, first conductivity type semiconductor region), and a start-up current I_{T} is passed to the bias circuit 30a through the diode 32. Thus, the diffusion resistor 15 (p-type semiconductor region, first conductivity type semiconductor region) and the limiting resistor 16 operate as a start-up circuit. Here, the limiting resistor 16 may be omitted as in the power supply circuit 60a.

Thus, the power supply circuit 60c of this practical example is a power supply circuit allowing start-up control by an optical signal. Furthermore, under intense optical irradiation, the start-up current output of the start-up circuit 10c also increases, and hence the bias circuit 30a can be stably started up.

In the illustrative configuration of the power supply circuits 60a-60c, the bias circuit 30a outputs two biases OUT, i.e., output currents I₁ and I₂. However, the invention is not limited thereto, but a similar configuration can be used to output any number of currents. Furthermore, the bias circuit 30a is not limited to the aforementioned current source circuit, but is also applicable to a voltage source circuit.

### Second Embodiment

In the illustrative configuration of the power supply circuits 60-60c, start-up currents are passed into the bias circuits 30 and 30a when the bias circuits 30 and 30a are driven. However, a configuration of drawing a start-up current from the bias circuit is also possible.

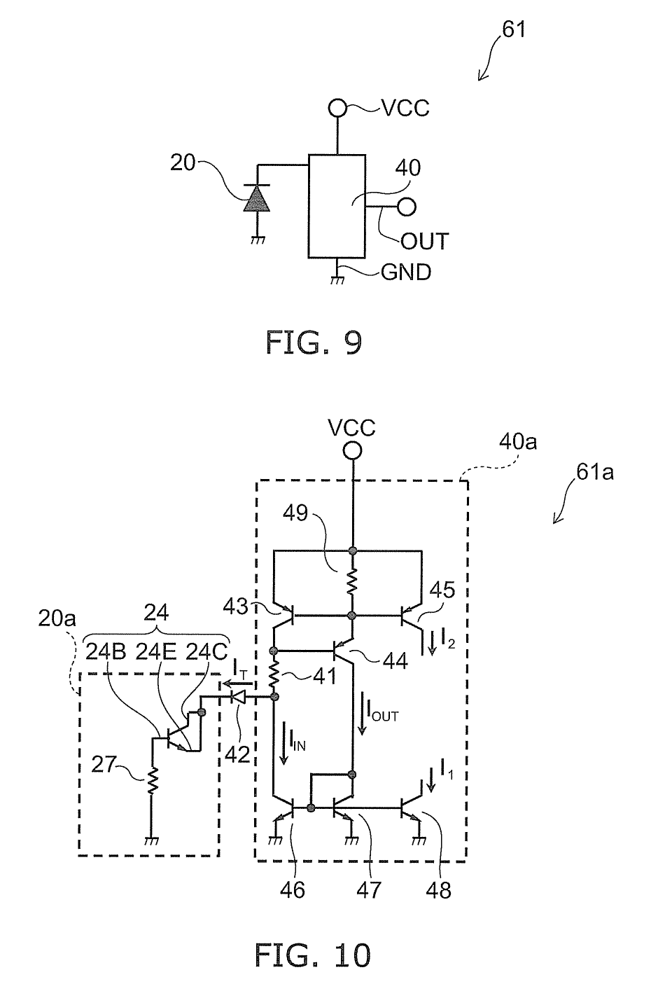

FIG. 9 is a block diagram illustrating the configuration of a power supply circuit according to another embodiment of the invention.

As shown in FIG. 9, the power supply circuit 61 has a one-chip structure in which a bias circuit 40 and a start-up circuit 20 are formed in the same semiconductor substrate.

The bias circuit 40 is an electronic circuit connected to the output of the start-up circuit 20 and supplying a bias OUT to the outside. However, it is an electronic circuit requiring a start-up circuit and does not operate even if power is applied. When an optical signal is entered after power-on, or at power-on while an optical signal is entered, the bias circuit 40 normally starts operation by a photocurrent flowing into the start-up circuit 20.

Thus, the power supply circuit 61 is a power supply, which supplies the bias OUT to the outside not immediately when the power is on, but when an optical signal is further entered.

The start-up circuit 20 serves to convert an optical signal to an electrical signal. When an optical signal is inputted, the start-up circuit 20 draws a photocurrent from the bias circuit 40 and places it in start-up state. In this practical example, the start-up circuit 20 is illustratively composed of a photodiode, and its n-type semiconductor region (first conductivity type semiconductor region) is electrically connected to the bias circuit 40. However, the invention is not limited thereto. The start-up circuit 20 can be composed of any element converting an optical signal to an electrical signal, such as a parasitic diode of a bipolar transistor, resistor, capacitor or the like, and its n-type semiconductor region (first conductivity type semiconductor region) can be electrically connected to the bias circuit 40.

FIG. 10 is a circuit diagram illustrating another practical example of the invention.

As shown in FIG. 10, the power supply circuit 61a has a one-chip structure in which a bias circuit 40a and a start-up circuit 20a are formed in the same semiconductor substrate.

In the power supply circuit 61a, the bias circuit 40a requiring a start-up circuit is illustratively a self-biasing current source circuit referenced to the base-emitter voltage Vbe. The start-up circuit 20a includes an NPN transistor 24 and a limiting resistor 27.

The NPN transistor 24 of the start-up circuit 20a includes a collector 24C, an emitter 24E, and a base 24B. The base 24B is connected to one end of the limiting resistor 27. The other end of the limiting resistor 27 is connected to low potential, such as ground GND. The collector 24C and the emitter 24E are connected to the bias circuit 40a through a diode 42.

The bias circuit 40a has a configuration similar to that of the bias circuit 30a shown in FIG. 2 except that the PNP transistors and the NPN transistors are interchanged with each other and inverted between the power supply VCC and the ground GND. Thus, the operation of the bias circuit 40a is similar to that of the bias circuit 30a, and the description thereof is omitted.

In the bias circuit 40a, like the bias circuit 30a, no current flows at the instant of power-on. Hence, the bias circuit 40a without the start-up circuit 20a is unable to drive itself out of the zero-current state.

When there is no optical irradiation and the start-up circuit 20a does not act on the bias circuit 40a, no current flows in the bias circuit 40a. Hence, the base-emitter voltage of the transistors 43 and 44 of the bias circuit 40a is nearly zero, and the collector 24C and the emitter 24E of the NPN transistor 24 are placed at high potential (power supply potential VCC).

The NPN transistor 24 has a configuration similar to that of the NPN transistor 13 shown in FIG. 3. The collector 24C and the emitter 24E are placed at high potential, and the base 24B is placed at low potential. The collector-substrate junction, the collector-base junction, and the emitter-base junction are reverse biased and create reverse biased parasitic diodes Dcv, Dcb, and Deb, respectively.

In the case where there is no optical signal, the parasitic diodes Dcv, Dcb, and Deb are reverse biased, and current barely flows therein. Hence, because the base current and the collector current barely flow in the NPN transistor 24, it draws no start-up current from the bias circuit 40a.

Next, the operation in the presence of an optical signal is described. Because the parasitic diodes Dcv, Dcb, and Deb are reverse biased, an optical signal entered thereto is photoelectrically converted at each junction interface, and a current flows from the cathode toward the anode of each of the parasitic diodes Dcv, Dcb, and Deb. Because the collector 24C and the emitter 24E are connected to the high potential side, the current flowing in each of the parasitic diodes Dcv, Dcb, and Deb is supplied from the collector 24C and emitter 24E.

In the parasitic diode Dcv, the current flows from the collector 24C toward the p-type semiconductor substrate 50. In the parasitic diode Dcb, the current flows from the collector 24C to the base 24B. In the parasitic diode Deb, the current flows from the emitter 24E toward the base 24B. Hence, the current flowing in the parasitic diodes Dcb and Deb flows out from the base 24B of the NPN transistor 24. Thus, the current flowing in the parasitic diodes Dcv, Dcb, and Deb is drawn from the collector 24C and the emitter 24E of the NPN transistor 24. This current is drawn from the bias circuit 40a through the diode 42.

When an optical signal is entered after power-on, or at power-on while an optical signal is entered, a current is drawn to the collector 24C and the emitter 24E of the NPN transistor 24, and a start-up current I_{T} is passed from the bias circuit 40a. Thus, the NPN transistor 24 and the limiting resistor 27 operate as a start-up circuit for the bias circuit 40a. Here, although the limiting resistor 27 is inserted to limit the photocurrent, it may be omitted.

Thus, the power supply circuit 61a of this practical example is a power supply circuit allowing start-up control by an optical signal. Furthermore, under intense optical irradiation, the start-up current output of the start-up circuit 20a also increases, and hence the bias circuit 40a can be stably started up.

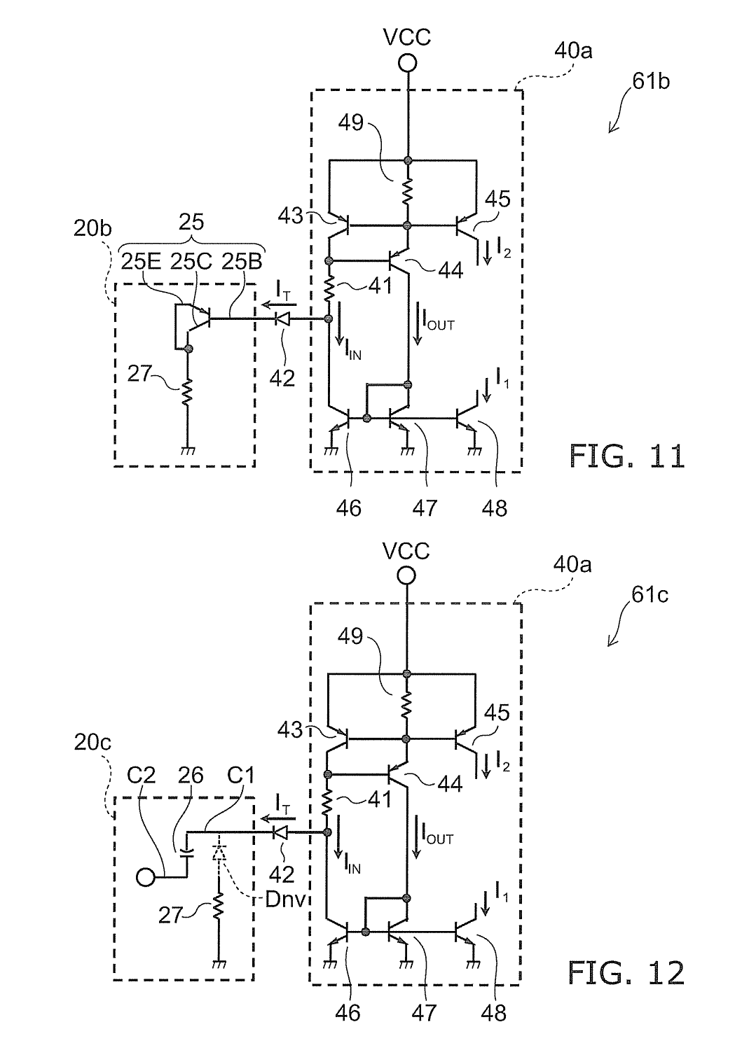

FIG. 11 is a circuit diagram illustrating another practical example of the invention.

As shown in FIG. 11, the power supply circuit 61b has a one-chip structure in which a bias circuit 40a and a start-up circuit 20b are formed in the same semiconductor substrate.

The start-up circuit 20b includes a PNP transistor 25 and a limiting resistor 27.

The PNP transistor 25 includes a collector 25C, an emitter 25E, and a base 25B. The collector 25C and the emitter 25E are connected to one end of the limiting resistor 27. The other end of the limiting resistor 27 is connected to low potential, such as ground GND. That is, the collector 25C and the emitter 25E are connected to low potential. The base 25B is connected to the bias circuit 40a through a diode 42. Here, when the start-up circuit 20b does not act on the bias circuit 40a, no current flows in the bias circuit 40a. Hence, the base 25B of the PNP transistor 25 is placed at high potential. The rest is similar to the power supply circuit 61a, and hence the description thereof is omitted.

The PNP transistor 25 has a configuration similar to that of the PNP transistor 14 shown in FIG. 6. The collector 25C and the emitter 25E are placed at low potential, and the base 25B is placed at high potential. The base-substrate junction, the base-collector junction, and the base-emitter junction are reverse biased and create reverse biased parasitic diodes Dbv, Dbc, and Dbe, respectively.

In the case where there is no optical signal, the parasitic diodes Dbv, Dbc, and Dbe are reverse biased, and current barely flows therein. Hence, because the base current and the collector current barely flow in the PNP transistor 25, it draws no start-up current from the bias circuit 40a.

Because the parasitic diodes Dbv, Dbc, and Dbe are reverse biased, an optical signal entered thereto is photoelectrically converted at each junction interface, and a current flows from the cathode toward the anode of each parasitic diode. Because the base 25B is connected to the high potential side, the current flowing in each of the parasitic diodes Dbv, Dbc, and Dbe is supplied from the base 25B. In the parasitic diode Dbv, the current flows from the base 25B toward the p-type semiconductor substrate 50. In the parasitic diode Dbc, the current flows from the base 25B to the collector 25C. In the parasitic diode Dbe, the current flows from the base 25B to the emitter 25E. Hence, the current flowing in the parasitic diodes Dbc and Dbe is drawn from the base 25B of the PNP transistor 25.

When an optical signal is entered after power-on, or at power-on while an optical signal is entered, a current is drawn to the base 25B of the PNP transistor 25, and a start-up current I_{T} is passed from the bias circuit 40a through the diode 42. Thus, the PNP transistor 25 and the limiting resistor 27 operate as a start-up circuit. Here, the limiting resistor 27 may be omitted as in the power supply circuit 61a.

Thus, the power supply circuit 61b of this practical example is a power supply circuit allowing start-up control by an optical signal. Furthermore, under intense optical irradiation, the start-up current drawn by the start-up circuit 20b also increases, and hence the bias circuit 40a can be stably started up.

FIG. 12 is a circuit diagram illustrating another practical example of the invention.

As shown in FIG. 12, the power supply circuit 61c has a one-chip structure in which a bias circuit 40a and a start-up circuit 20c are formed in the same semiconductor substrate.

The start-up circuit 20c includes a capacitor 26 and a limiting resistor 27.

The terminal C1 on the semiconductor substrate side of the capacitor 26 (the cathode of the parasitic diode Dnv) is connected to the bias circuit 40a through a diode 42. Furthermore, the capacitor 26 is connected to one end of the limiting resistor 27 through a parasitic diode Dnv. The other end of the limiting resistor 27 is connected to low potential, such as ground GND. In other words, the anode of the parasitic diode Dnv of the capacitor 26 is connected to low potential. Here, when the start-up circuit 20c does not act on the bias circuit 40a, no current flows in the bias circuit 40a. Hence, the terminal C1 of the capacitor 26 is placed at high potential. The rest is similar to the power supply circuit 61a, and hence the description thereof is omitted.

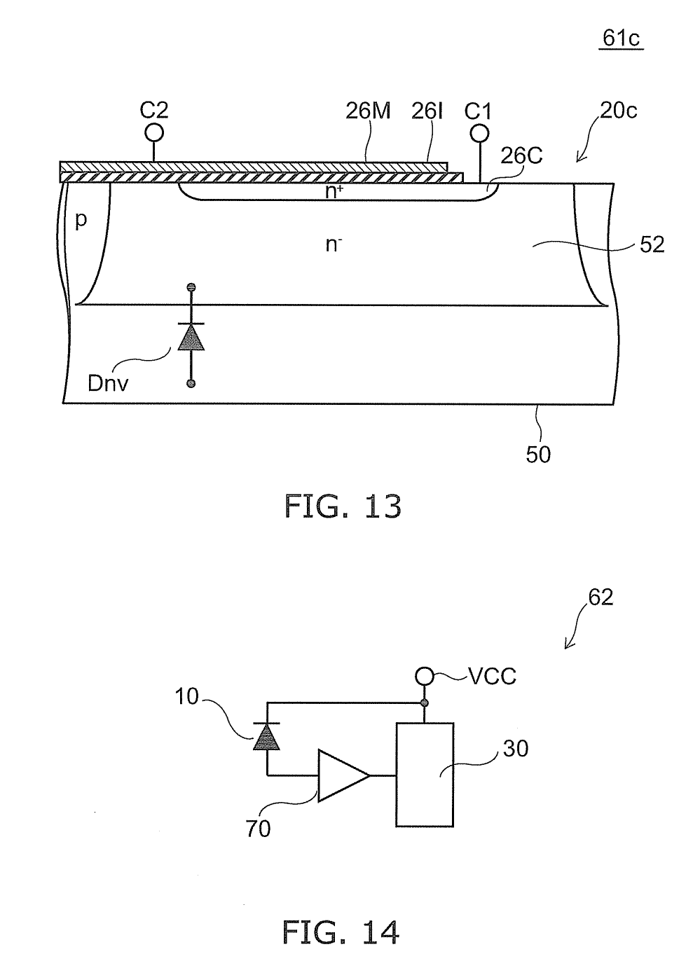

FIG. 13 is a schematic cross-sectional view of the capacitor of the start-up circuit shown in FIG. 12.

As shown in FIG. 13, the capacitor 26 of the start-up circuit 20c is a capacitor in which an insulating film 261 provided on a p-type semiconductor substrate 50 (p-type semiconductor region, second conductivity type semiconductor region) serves as a dielectric. An n⁻-well region 52 (n-type semiconductor region, first conductivity type semiconductor region) is provided in the p-type semiconductor substrate 50 (p-type semiconductor region, second conductivity type semiconductor region). An n⁺-contact layer 26C (n-type semiconductor region, first conductivity type semiconductor region) is provided in the n⁻-well region 52 (n-type semiconductor region, first conductivity type semiconductor region) and serves as one electrode C1 of the capacitor. Furthermore, an electrode 26M is provided via the insulating film 261 above the n⁻-well region 52 (n-type semiconductor region, first conductivity type semiconductor region) and the n⁺-contact layer 26C (n-type semiconductor region, first conductivity type semiconductor region) and serves as the other electrode of the capacitor 26. Thus, the capacitor 26 is formed between the electrodes C1 and C2.

Because the n⁺-contact layer 26C (n-type semiconductor region, first conductivity type semiconductor region) is placed at high potential, the n⁻-well region 52 (n-type semiconductor region, first conductivity type semiconductor region) is placed at high potential. Furthermore, because the p-type semiconductor substrate 50 (p-type semiconductor region, second conductivity type semiconductor region) is placed at low potential, the junction between the n⁻-well region 52 (n-type semiconductor region, first conductivity type semiconductor region) and the p-type semiconductor substrate 50 (p-type semiconductor region, second conductivity type semiconductor region) is reverse biased and creates a reverse biased parasitic diode Dnv.

In the case where there is no optical signal, the parasitic diode Dnv is reverse biased, and current barely flows therein. Hence, no start-up current is drawn from the bias circuit 40a toward the capacitor 26.

Next, the operation in the presence of an optical signal is described. Because the parasitic diode Dnv is reverse biased, an optical signal entered thereto is photoelectrically converted at the junction interface, and a current flows from the cathode toward the anode of the parasitic diode. Because the n⁻-well region 52 (n-type semiconductor region, first conductivity type semiconductor region) is connected to the high potential side through the n⁺-contact layer 26C (n-type semiconductor region, first conductivity type semiconductor region), the current flowing in the parasitic diode Dnv is supplied from the n⁺-contact layer 26C (n-type semiconductor region, first conductivity type semiconductor region). In the parasitic diode Dnv, the current flows from the n⁻-well region 52 (n-type semiconductor region, first conductivity type semiconductor region) toward the p-type semiconductor substrate 50 (p-type semiconductor region, second conductivity type semiconductor region). Hence, the current flowing in the parasitic diode Dnv is drawn from the terminal C1 of the capacitor 26.

When an optical signal is entered after power-on, or at power-on while an optical signal is entered, a current is drawn to the terminal C1 of the capacitor 26, and a start-up current I_{T} is passed to the bias circuit 40a through the diode 42. Thus, the capacitor 26 and the limiting resistor 27 operate as a start-up circuit. Here, the limiting resistor 27 may be omitted as in the power supply circuit 61a.

Thus, the power supply circuit 61c of this practical example is a power supply circuit allowing start-up control by an optical signal. Furthermore, under intense optical irradiation, the start-up current drawn by the start-up circuit 20c also increases, and hence the bias circuit 40a can be stably started up.

In the illustrative configuration of the power supply circuits 61-61c, the bias circuit 40a outputs two biases OUT, i.e., output currents I₁ and I₂. However, the invention is not limited thereto, but a similar configuration can be used to output any number of currents. Furthermore, the bias circuit 40a is not limited to the aforementioned current source circuit, but is also applicable to a voltage source circuit.

### Third Embodiment

In the aforementioned start-up circuits 10-10c, the start-up current I_{T} is determined by the area of the start-up element. However, the area of the start-up element may be extremely increased to obtain a required start-up current. In this context, a power supply circuit 62 may include an amplifier circuit 70 for amplifying each start-up current I_{T} of the start-up circuits 10-10c.

FIG. 14 is a block diagram illustrating the configuration of a power supply circuit according to another embodiment of the invention.

As shown in FIG. 14, in the power supply circuit 62, an amplifier circuit 70 is interposed between a start-up circuit 10 and a bias circuit 30. More specifically, the p-type semiconductor region (first conductivity type semiconductor region) of the start-up circuit 10 is electrically connected to the input of the amplifier circuit 70, and the output of the amplifier circuit 70 is electrically connected to the bias circuit 30. Thus, the area of the start-up circuit 10 can be reduced. The rest is the same as the power supply circuit 60 shown in FIG. 1, and hence the description thereof is omitted.

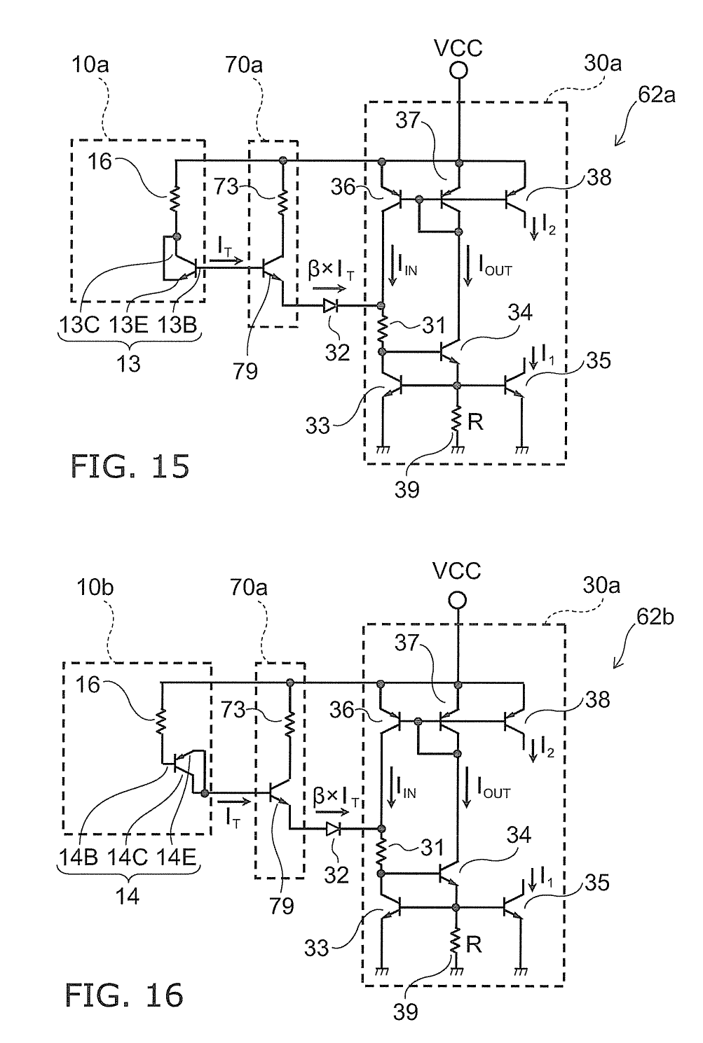

FIG. 15 is a circuit diagram illustrating another practical example of the invention.

As shown in FIG. 15, the power supply circuit 62a has a one-chip structure in which a bias circuit 30a, a start-up circuit 10a, and an amplifier circuit 70a are formed in the same semiconductor substrate. The input of the amplifier circuit 70a is connected to the base 13B of the transistor 13 of the start-up circuit 10a, that is, electrically connected to the p-type semiconductor region (first conductivity type semiconductor region) of the start-up circuit 10a. The output of the amplifier circuit 70a is connected to the bias circuit 30a through a diode 32. The start-up circuit 10a and the bias circuit 30a are similar to those of the power supply circuit 60a shown in FIG. 2, and hence the description thereof is omitted.

The amplifier circuit 70a includes an NPN transistor 79 and a limiting resistor 73, receives as input the start-up current I_{T}, which is the output of the start-up circuit 10a, and amplifies it for output to the bias circuit 30a. Denoting by β the current amplification factor of the amplifier circuit 70a, the start-up current I_{T} outputted from the start-up circuit 10a is multiplied by β into β×I_{T}, which is inputted to the bias circuit 30a.

Thus, the start-up current inputted to the bias circuit 30a is multiplied by β by the amplifier circuit 70a. Hence, the area of the NPN transistor 13 used in the start-up circuit 10a can be reduced by a factor of β. In addition, the limiting resistor 73 may be omitted.

FIG. 16 is a circuit diagram illustrating another practical example of the invention.

As shown in FIG. 16, the power supply circuit 62b has a one-chip structure in which a bias circuit 30a, a start-up circuit 10b, and an amplifier circuit 70a are formed in the same semiconductor substrate. The input of the amplifier circuit 70a is connected to the collector 14C and the emitter 14E of the transistor 14 of the start-up circuit 10b, that is, electrically connected to the p-type semiconductor region (first conductivity type semiconductor region) of the start-up circuit 10b. The output of the amplifier circuit 70a is connected to the bias circuit 30a through a diode 32. The start-up circuit 10b and the bias circuit 30a are similar to those of the power supply circuit 60b shown in FIG. 5, and hence the description thereof is omitted.

The amplifier circuit 70a is similar to that of the power supply circuit 62a shown in FIG. 15.

Also in the power supply circuit 62b, denoting by p the current amplification factor of the amplifier circuit 70a, the start-up current is multiplied by p. Hence, the area of the PNP transistor 14 used in the start-up circuit 10b can be reduced by a factor of β. Also in this practical example, the limiting resistor 73 may be omitted.

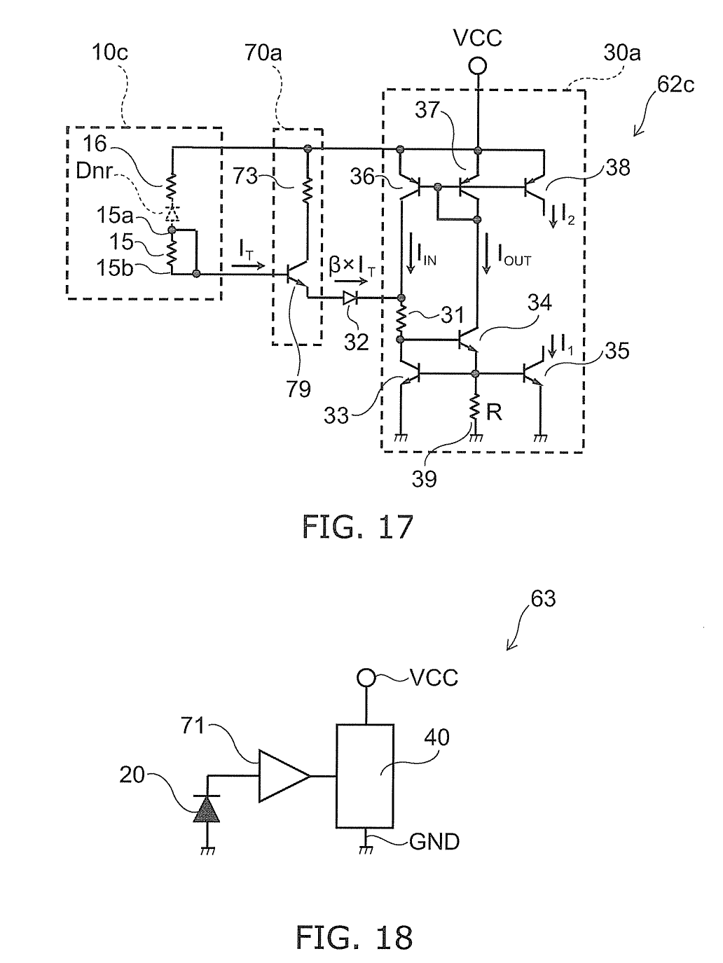

FIG. 17 is a circuit diagram illustrating another practical example of the invention.

As shown in FIG. 17, the power supply circuit 62c has a one-chip structure in which a bias circuit 30a, a start-up circuit 10c, and an amplifier circuit 70a are formed in the same semiconductor substrate. The input of the amplifier circuit 70a is connected to both terminals 15a and 15b of the diffusion resistor 15 of the start-up circuit 10c, that is, electrically connected to the p-type semiconductor region (first conductivity type semiconductor region) of the start-up circuit 10c. The output of the amplifier circuit 70a is connected to the bias circuit 30a through a diode 32. The start-up circuit 10c and the bias circuit 30a are similar to those of the power supply circuit 60c shown in FIG. 7, and hence the description thereof is omitted.

The amplifier circuit 70a is similar to that of the power supply circuit 62a shown in FIG. 15.

Also in the power supply circuit 62c, denoting by β the current amplification factor of the amplifier circuit 70a, the start-up current is multiplied by β. Hence, the area of the diffusion resistor 15 used in the start-up circuit 10c can be reduced by a factor of β. Also in this practical example, the limiting resistor 73 may be omitted.

### Fourth Embodiment

Likewise, in the start-up circuits 20-20c, the start-up current I_{T} is determined by the area of the start-up element. However, the area of the start-up element may be extremely increased to obtain a required start-up current. In this context, a power supply circuit 63 may include an amplifier circuit 71 for amplifying each start-up current I_{T} of the start-up circuits 20-20c.

FIG. 18 is a block diagram illustrating the configuration of a power supply circuit according to another embodiment of the invention.

As shown in FIG. 18, in the power supply circuit 63, an amplifier circuit 71 is interposed between a start-up circuit 20 and a bias circuit 40. More specifically, the n-type semiconductor region (first conductivity type semiconductor region) of the start-up circuit 20 is electrically connected to the input of the amplifier circuit 71, and the output of the amplifier circuit 71 is electrically connected to the bias circuit 40. Thus, the area of the start-up circuit 20 can be reduced. The rest is similar to the power supply circuit 61 shown in FIG. 9, and hence the description thereof is omitted.

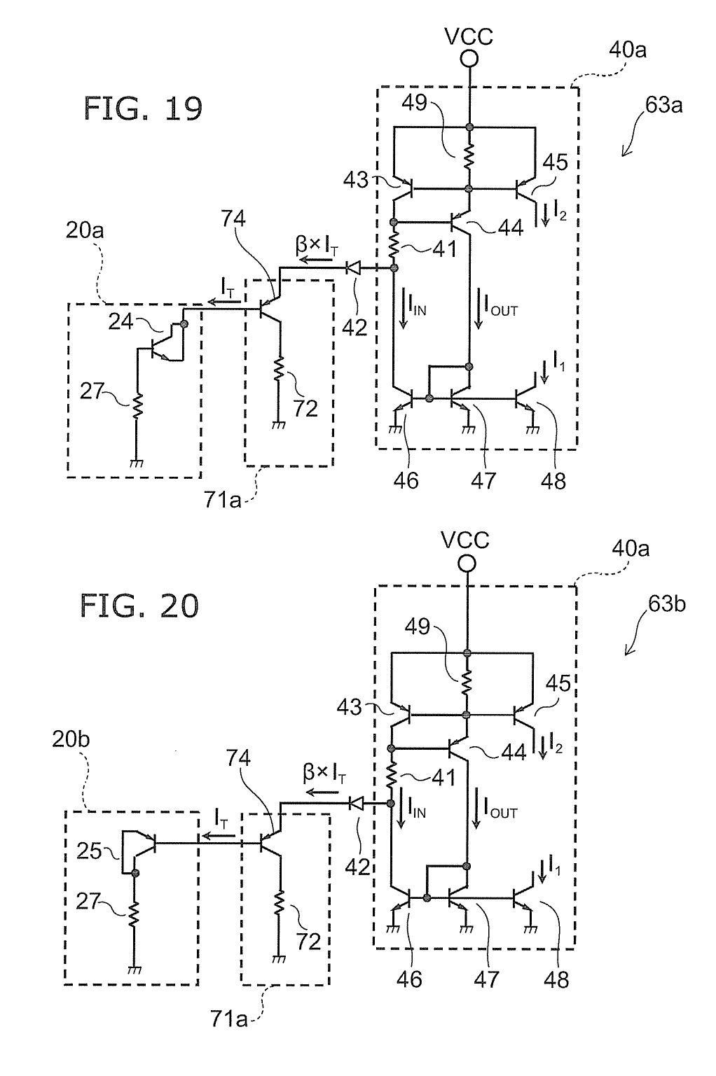

FIG. 19 is a circuit diagram illustrating another practical example of the invention.

As shown in FIG. 19, the power supply circuit 63a has a one-chip structure in which a bias circuit 40a, a start-up circuit 20a, and an amplifier circuit 71a are formed in the same semiconductor substrate. The input of the amplifier circuit 71a is connected to the collector and the emitter of the transistor 24 of the start-up circuit 20a, that is, electrically connected to the n-type semiconductor region (first conductivity type semiconductor region) of the start-up circuit 20a. The output of the amplifier circuit 71a is connected to the bias circuit 40a through a diode 42. The start-up circuit 20a and the bias circuit 40a are similar to those of the power supply circuit 61a shown in FIG. 10, and hence the description thereof is omitted.

The amplifier circuit 71a includes a PNP transistor 74 and a limiting resistor 72, amplifies the start-up current I_{T} inputted to the start-up circuit 20a, and draws it from the bias circuit 40a. Denoting by β the current amplification factor of the amplifier circuit 71a, the start-up current I_{T} inputted to the start-up circuit 20a is multiplied by β into β×I_{T}, which is drawn from the bias circuit 40a.

Thus, the start-up current drawn from the bias circuit 40a is multiplied by β by the amplifier circuit 71a. Hence, the area of the NPN transistor 24 used in the start-up circuit 20a can be reduced by a factor of β. In addition, the limiting resistor 72 may be omitted.

FIG. 20 is a circuit diagram illustrating another practical example of the invention.

As shown in FIG. 20, the power supply circuit 63b has a one-chip structure in which a bias circuit 40a, a start-up circuit 20b, and an amplifier circuit 71a are formed in the same semiconductor substrate. The input of the amplifier circuit 71a is connected to the base of the transistor 25 of the start-up circuit 20b, that is, electrically connected to the n-type semiconductor region (first conductivity type semiconductor region) of the start-up circuit 20b. The output of the amplifier circuit 71a is connected to the bias circuit 40a through a diode 42. The start-up circuit 20b and the bias circuit 40a are similar to those of the power supply circuit 61b shown in FIG. 11, and hence the description thereof is omitted.

The amplifier circuit 71a is similar to that of the power supply circuit 63a shown in FIG. 19.

Also in the power supply circuit 63b, denoting by β the current amplification factor of the amplifier circuit 71a, the start-up current drawn from the bias circuit 40a is multiplied by β by the amplifier circuit 71a. Hence, the area of the PNP transistor 25 used in the start-up circuit 20b can be reduced by a factor of β. In addition, the limiting resistor 72 may be omitted.

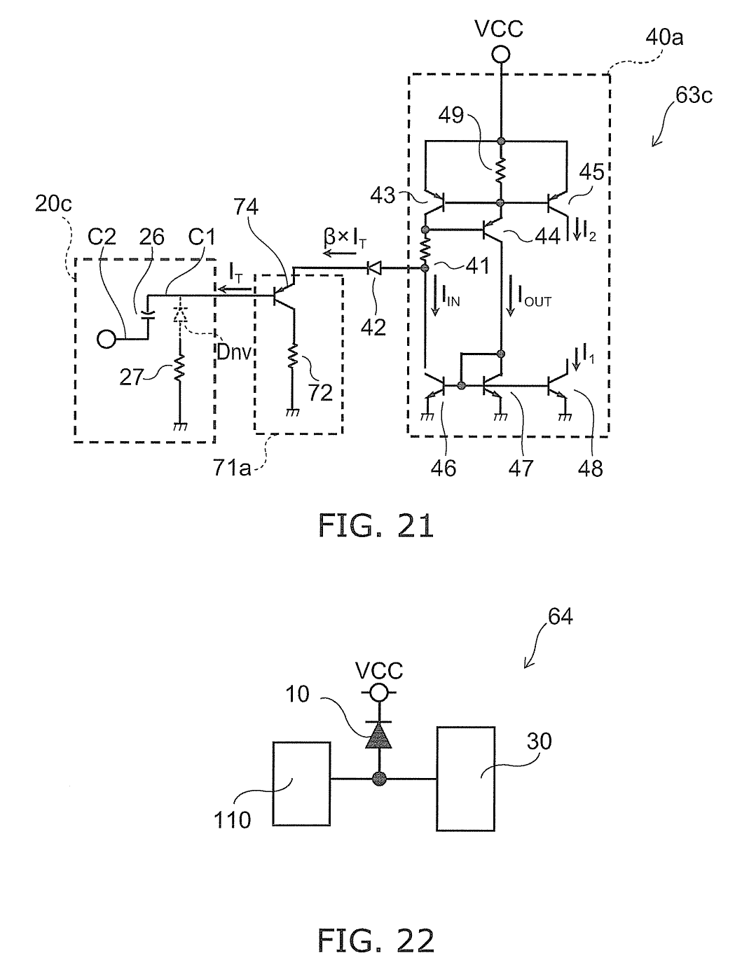

FIG. 21 is a circuit diagram illustrating another practical example of the invention.

As shown in FIG. 21, the power supply circuit 63c has a one-chip structure in which a bias circuit 40a, a start-up circuit 20c, and an amplifier circuit 71a are formed in the same semiconductor substrate. The input of the amplifier circuit 71a is connected to the terminal C1 of the capacitor 26 of the start-up circuit 20c, that is, electrically connected to the n-type semiconductor region (first conductivity type semiconductor region) of the start-up circuit 20c. The output of the amplifier circuit 71a is connected to the bias circuit 40a through a diode 42. The start-up circuit 20c and the bias circuit 40a are similar to those of the power supply circuit 61c shown in FIG. 12, and hence the description thereof is omitted.

The amplifier circuit 71a is similar to that of the power supply circuit 63a shown in FIG. 19.

Also in the power supply circuit 63c, denoting by β the current amplification factor of the amplifier circuit 71a, the start-up current drawn from the bias circuit 40a is multiplied by β by the amplifier circuit 71a. Hence, the area of the capacitor 26 used in the start-up circuit 20c can be reduced by a factor of β. In addition, the limiting resistor 72 may be omitted.

Thus, the power supply circuits 62-62c and 63-63c are power supply circuits allowing start-up control by an optical signal. Furthermore, even under intense optical irradiation, the bias circuits 30-30a and 40-40a can be stably started up.

### Fifth Embodiment

The aforementioned power supply circuits 60-63c are illustratively based on optically driven start-up circuits. However, a conventional start-up circuit can be used as an auxiliary start-up circuit for assisting the start-up circuit of the invention.

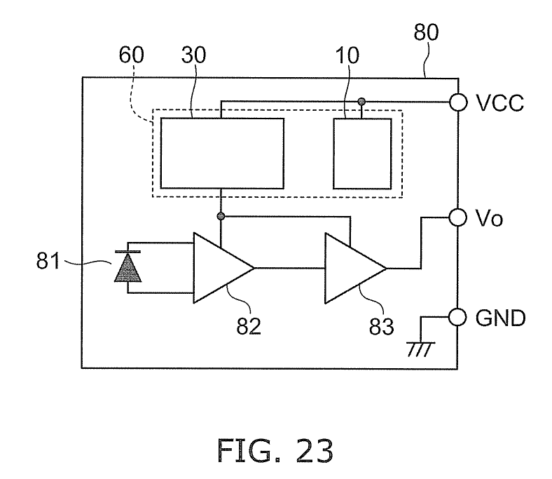

FIG. 22 is a block diagram illustrating the configuration of a power supply circuit according to another embodiment of the invention.

As shown in FIG. 22, the power supply circuit 64 has a one-chip structure in which a bias circuit 30, an optically driven start-up circuit 10, and an auxiliary start-up circuit 110 composed of a diode and the like are formed in the same semiconductor substrate. The start-up current from the auxiliary start-up circuit 110 is inputted to the bias circuit 30 together with the start-up current from the start-up circuit 10. The rest is similar to the power supply circuit 60 shown in FIG. 1, and hence the description thereof is omitted.

In the power supply circuit 64, a configuration of injecting a start-up current is illustrated. The auxiliary start-up circuit 110 composed of a diode and the like is operative to inject a start-up current into the bias circuit 30 requiring a start-up circuit. Furthermore, the optically driven start-up circuit 10 is connected parallel to the auxiliary start-up circuit 110. The start-up circuit 10 and the auxiliary start-up circuit 110 assist each other. Thus, the area required for the optically driven start-up circuit 10 can be reduced.

In particular, in the case where the bias circuit 30 requiring a start-up circuit is a bias circuit for a TIA (trans impedance amplifier) circuit, it is necessary to address variation in the consumption current of the TIA, which depends on the presence or absence of the optical signal. For a circuit configuration in which the consumption current increases in the presence of the optical signal, the consumption current of the bias circuit 30 significantly increases under intense optical irradiation, and the start-up current from the existing auxiliary start-up circuit 110 alone may be insufficient. To address this case by using the existing auxiliary start-up circuit 110 alone, the circuit needs to be designed so as to generate a large start-up current, which unfortunately results in increasing the consumption current.

Furthermore, in the case where the auxiliary start-up circuit 110 has a conventional configuration composed of a diode and the like, the behavior of the auxiliary start-up circuit 110 is varied in the presence of an intense optical signal. Hence, a large current needs to be passed for reliable start-up of the bias circuit 30.

In this context, an optically driven start-up circuit 10 is provided parallel to the auxiliary start-up circuit 110. This can address the case of intense optical irradiation while suppressing the consumption current of the auxiliary start-up circuit 110.

In this practical example, the optically driven start-up circuit 10 is illustratively used. However, other start-up circuits 10a-10c and 20-20c can also be used.

As described above, in the power supply circuits 60-64, the area of the portion constituting the start-up circuit can be reduced, and this makes the circuit area of the overall electronic device small. Furthermore, even in the presence of an intense optical signal, the bias circuit can be reliably started up to operate the power supply circuit.

These power supply circuits are desirably used in electronic circuits for receiving an optical signal, such as photocouplers and optical transmission modules.

FIG. 23 is a block diagram illustrating the configuration of an optical receiving circuit according to another embodiment of the invention.

As shown in FIG. 23, the optical receiving circuit 80 has a one-chip structure including a power supply circuit 60, a photocurrent converting element 81, a TIA 82, and an output circuit 83.

The photocurrent converting element 81 is an element for converting an optical signal to a photocurrent. The photocurrent is converted to a voltage by the TIA 82, and further converted to an output Vo by the output circuit 83.

The power supply circuit 60 includes a start-up circuit 10 and a bias circuit 30 and supplies a bias to the TIA 82 and the output circuit 83.

In the case where there is no optical signal, the power supply circuit 60 supplies no bias to the photocurrent converting element 81, the TIA 82, and the output circuit 83. Hence, even after power-on, the output Vo is zero. Thus, no noise is generated in the output Vo at power-on.

When an optical signal is entered after power-on, or at power-on while an optical signal is entered, the bias circuit 30 is started up by the start-up circuit 10, and the power supply circuit 60 starts to supply a bias to the photocurrent converting element 81, the TIA 82, and the output circuit 83.

Thus, the optical receiving circuit 80 of this practical example is an optical receiving circuit allowing start-up control by an optical signal. It allows stable operation with a small chip area, even under intense optical irradiation. Furthermore, in the case where there is no optical signal, no noise is generated in the output Vo at power-on.

The embodiments of the invention have been described with reference to examples. However, the invention is not limited to these examples. For instance, various specific configurations of the components constituting the power supply circuit and the optical receiving circuit are encompassed within the scope of the invention as long as those skilled in the art can similarly practice the invention and achieve similar effects by suitably selecting such configurations from conventionally known ones.

Furthermore, any two or more components of the examples can be combined with each other as long as technically feasible, and such combinations are also encompassed within the scope of the invention as long as they fall within the spirit of the invention.

Furthermore, those skilled in the art can suitably modify and implement the power supply circuit and the optical receiving circuit described above in the embodiments of the invention, and all the power supply circuits and the optical receiving circuits thus modified are also encompassed within the scope of the invention as long as they fall within the spirit of the invention.

Furthermore, those skilled in the art can conceive various modifications and variations within the spirit of the invention, and it is understood that such modifications and variations are also encompassed within the scope of the invention.

1. A power supply circuit comprising:
a start-up circuit provided on a semiconductor substrate and configured to convert an optical signal to an electrical signal; and
a bias circuit provided on the semiconductor substrate and being in a non-start-up state at power-on,
the start-up circuit including:
a p-type semiconductor region; and
an n-type semiconductor region provided in contact with the p-type semiconductor region,
the p-type semiconductor region being electrically connected to the bias circuit,
the n-type semiconductor region being electrically connected to a power supply of the bias circuit, and
the bias circuit entering a start-up state by a current flowing in the start-up circuit.

2. The circuit according to claim 1, further comprising:
an amplifier circuit electrically connected to the p-type semiconductor region,
the amplifier circuit having an output electrically connected to the bias circuit.

3. The circuit according to claim 1, further comprising:
an auxiliary start-up circuit configured to start up the bias circuit,
the auxiliary start-up circuit having an output electrically connected to the bias circuit.

4. The circuit according to claim 1, wherein
the start-up circuit includes an NPN transistor, and
the p-type semiconductor region is a base of the NPN transistor, and the n-type semiconductor region is an emitter and a collector of the NPN transistor.

5. The circuit according to claim 1, wherein
the start-up circuit includes a PNP transistor, and
the p-type semiconductor region is an emitter and a collector of the PNP transistor, and the n-type semiconductor region is a base of the PNP transistor.

6. The circuit according to claim 1, wherein
the start-up circuit includes a diffusion resistor provided on the n-type semiconductor region, and
the p-type semiconductor region is a p-type diffusion layer of the diffusion resistor.

7. The circuit according to claim 1, wherein
the start-up circuit further includes a limiting resistor, and
the n-type semiconductor region is electrically connected to the power supply of the bias circuit through the limiting resistor.

8. A power supply circuit comprising:
a start-up circuit provided on a semiconductor substrate and configured to convert an optical signal to an electrical signal; and
a bias circuit provided on the semiconductor substrate and being in a non-start-up state at power-on,
the start-up circuit including:
an n-type semiconductor region; and
a p-type semiconductor region provided in contact with the n-type semiconductor region,
the n-type semiconductor region being electrically connected to the bias circuit,
the p-type semiconductor region being electrically connected to ground of the bias circuit, and
the bias circuit entering a start-up state by a current flowing in the start-up circuit.

9. The circuit according to claim 8, further comprising:
an amplifier circuit electrically connected to the n-type semiconductor region,
the amplifier circuit having an output electrically connected to the bias circuit.

10. The circuit according to claim 8, further comprising:
an auxiliary start-up circuit configured to start up the bias circuit,
the auxiliary start-up circuit having an output electrically connected to the bias circuit.

11. The circuit according to claim 8, wherein
the start-up circuit includes an NPN transistor, and
the n-type semiconductor region is a collector and an emitter of the NPN transistor, and the p-type semiconductor region is a base of the PNP transistor.

12. The circuit according to claim 8, wherein
the start-up circuit includes a PNP transistor, and
the n-type semiconductor region is a base of the PNP transistor, and the p-type semiconductor region is an emitter and a collector of the PNP transistor.

13. The circuit according to claim 8, wherein
the start-up circuit includes a capacitor provided on the n-type semiconductor region, and
the n-type semiconductor region is an n⁺-contact layer constituting one electrode of the capacitor, and the p-type semiconductor region is the semiconductor substrate.

14. The circuit according to claim 8, wherein
the start-up circuit further includes a limiting resistor, and
the p-type semiconductor region is electrically connected to the ground of the bias circuit through the limiting resistor.

15. An optical receiving circuit comprising:
a power supply circuit;
a photocurrent converting element configured to convert optical energy to an electrical signal;
a current-voltage converting circuit configured to convert an output of the photocurrent converting element to a voltage; and
an output circuit configured to output an output of the current-voltage converting circuit,
the power supply circuit including:
a start-up circuit provided on a semiconductor substrate and configured to convert an optical signal to an electrical signal; and
a bias circuit provided on the semiconductor substrate and being in a non-start-up state at power-on,
the start-up circuit including:
a first conductivity type semiconductor region; and
a second conductivity type semiconductor region provided in contact with the first conductivity type semiconductor region,
the first conductivity type semiconductor region being electrically connected to the bias circuit,
the second conductivity type semiconductor region being electrically connected to a power supply of the bias circuit or ground, and
the bias circuit entering a start-up state by a current flowing in the start-up circuit.

16. The circuit according to claim 15, wherein
the start-up circuit includes an transistor, and
the first conductivity type semiconductor region is a base of the transistor, and the second conductivity type semiconductor region is an emitter and a collector of the transistor.

17. The circuit according to claim 15, wherein
the start-up circuit includes a transistor, and
the first conductivity type semiconductor region is an emitter and a collector of the transistor, and the second conductivity type semiconductor region is a base of the transistor.

18. The circuit according to claim 15, wherein
the start-up circuit further includes a limiting resistor, and
the second conductivity type semiconductor region is electrically connected to the power supply of the bias circuit or ground through the limiting resistor.

19. The circuit according to claim 15, wherein
the start-up circuit includes a diffusion resistor provided on the second conductivity type semiconductor region, and
the first conductivity type semiconductor region is a first conductivity type diffusion layer of the diffusion resistor.

20. The circuit according to claim 15, wherein
the start-up circuit includes a capacitor provided on the first conductivity type semiconductor region, and
the first conductivity type semiconductor region is an contact layer constituting one electrode of the capacitor, and the second conductivity type semiconductor region is the semiconductor substrate.
